(19) United States
(12) Patent Application Publication
(10) Pub. No.: US 2016/0142073 A1
(43) Pub. Date: May 19, 2016

(54) Access Control in a Network

(71) Applicant: TELEFONAKTIEBOLAGET L M ERICSSON (PUBL), Stockholm (SE)

(72) Inventors: Shiyuan Xiao, Shanghai (CN); Kun Chen, Shanghai (CN); Arnold Yang, Shanghai (CN)

(21) Appl. No.: 14/899,838

(22) PCT Filed: Jul. 10, 2013
(86) PCT No.: PCT/SE2013/050885

§ 371 Date: Dec. 18, 2015

(30) Foreign Application Priority Data
Jun. 20, 2013 (CN) PCT/CN2013/077540

(51) Int. Cl. H03M 13/09; H04L 1/00; H03M 13/00

(52) U.S. Cl. CPC H03M 13/09; H03M 13/617; H04L 1/0061

(57) ABSTRACT

The teachings relates to a method 200 performed in a processor 30, 32 for calculating a 10 bits Cyclic Redundancy Check, CRC, value for a message M(x). The method 200 comprises: determining 201 length of the message to be greater than 64 bits; adapting 202 the message 5 M(x) to have a length of n*128 bits, wherein n is a positive integral number, folding 203, n-1 times, of 128 bits by using a PCLMULQDQ instruction comprising performing a carry-less multiplication of two 64-bits operands; folding 204 of 64 bits by using the PCLMULQDQ instruction, providing a 64 bit message M′(x); 10 wherein the folding 203 of 128 bits and folding 204 of 64 bits are adapted for use of the PCLMULQDQ instruction to calculate a 10 bit CRC by: adapting degree of P(x) K(x) to 32 by setting K(x)=X²², wherein P(x) is a polynomial of degree 10, and wherein □ denotes the carry-less multiplication, and performing the folding of 128 bits 15 and folding of 64 bits by [M(x)∥x²²]mod[P(x)|x²²]; calculating 205 the 10 bits payload CRC value for the message M(x) by using a CRC-10 table-lookup algorithm.

### TECHNICAL FIELD

The technology disclosed herein relates generally to the field of error detection in networks, and in particular to calculation of cyclic redundancy check values in digital networks.

### BACKGROUND

Cyclic redundancy check (CRC) is an error-detecting code commonly used in digital networks in order to detect errors in storage or transmission of data, for example accidental changes to raw data. A CRC algorithm computes a checksum for a set of data to be sent or stored and appends it to the data, the checksum forming a code word. A device that receives such set of data including the checksum may perform a CRC on the code word and compare the resulting check value with an expected value. If the check value and the expected value do not match, an error is detected. Thereby, using CRC ensures that data being corrupted during transfer is detected.

CRC is used extensively in various types of networks, for example in the provision of different services in cellular networks. FIG. 1 illustrates an exemplary network 1, in particular a cellular network, implementing Long Term Evolution (LTE) standard. A wireless device 3 is provided with services via a network node 4, in the following exemplified by eNB or evolved Node B. The eNB 4 provides wireless communication links to the wireless device 3. Multimedia Broadcast and Multicast Services (MBMS) is a broadcasting service offered to the wireless device 3 via the network 1. An MBMS gateway 5 (MBMS-GW) is arranged to broadcast packets to all eNBs 4 within a service area, and a Broadcast Multicast Service Centre (BM-SC) 2 handles (e.g. schedules) the service to end-users, i.e. to the wireless device 3. The BM-SC 2 provides an entry point for external broadcast/multicast sources, i.e. for content providers. Different examples of content services 6 offered by such content providers are illustrated in the FIG. 1, e.g. satellite feeds, live feeds, Content Delivery Network (CDN) feeds, providing e.g. streaming and downloading to Internet users. The architecture illustrated in FIG. 1 comprises yet additional nodes, e.g. Operations Support System (OSS) 7 and Broadcast operations 8, and possibly still further nodes, not illustrated.

In such networks 1 CRC is typically used for ensuring accurate packet reception. In particular, by using CRC the eNB 4 is able to detect if any packets are corrupted during transmission from e.g. the BM-SC 2 to the eNB 4. The transmission of packets may in some instances need to be repeated, and the number of packets may become substantial and thus also the number of CRC calculations. The computations of the CRCs consume a vast amount of processor time.

One way of computing CRC is to implement a table-lookup algorithm, involving the use of pre-computed intermediate values to obtain the final CRC values. Although such CRC table-lookup algorithms are fast, their performance is still unsatisfactory and much processing time is still used in the nodes of the network 1 for calculating CRCs. In particular, with increasing data traffic there may be thousands of delivery sessions and several gigabits per second of traffic data. Processors, e.g. a Central Processing Unit (CPU), in the nodes of the networks use a large part of their processing time in order to perform all these calculations.

The payload CRC calculations taking up such large part of the CPU time leave less time to perform more urgent tasks, for example supporting concurrent delivery sessions and higher bitrate traffic.

However, with the explosion of high-speed networking over the past decade, one hardware server is expected to handle much heavier network traffic and CRC residue generation has become a significant difficulty, when using the traditional methods. Further increase in speed of performing the payload CRC calculations is therefore still desirable and needed.

### SUMMARY

An object of the invention is to overcome or at least alleviate one or more of the above-mentioned drawbacks.

The object is according to a first aspect achieved by a method performed in a processor calculating a 10 bits Cyclic Redundancy Check, CRC, value for a message M(x). The method comprises: determining the length of the message M(x) to be greater than 64 bits; adapting the message to have a length of n*128 bits, wherein n is a positive integral number; folding, n-1 times, of 128 bits by using a PCLMULQDQ instruction comprising performing a carry-less multiplication of two 64-bits operands; folding of 64 bits by using the PCLMULQDQ instruction, providing a 64 bit message M′(x); wherein the folding of 128 bits and folding of 64 bits are adapted for use of the PCLMULQDQ instruction to calculate a 10 bit CRC by:
adapting degree of P(x)·K(x) to 32 by setting K(x)=X²², wherein P(x) is a polynomial of degree 10, and wherein · denotes the carry-less multiplication,
performing the folding of 128 bits and folding of 64 bits by [M(x)·x²²]mod[P(x)·x^{22 ];}
   calculating the 10 bits payload CRC value for the message M(x) by using a CRC-10 table-lookup algorithm.

The method provides a CRC-10 algorithm that is faster and requires less CPU time than known methods, wherein the CRC-10 table-lookup algorithm is a bottleneck hindering improvements of throughput performance of network nodes from processor usage point of view.

The increased speed of CRC-10 calculations enables the CPU time to be used for other tasks, in particular more urgent tasks. Examples of such tasks comprise supporting concurrent delivery sessions and providing higher bitrate traffic. The increased speed of handling such tasks in turn results in an increased user satisfaction. Further, the increase in calculation speed may be obtained with the same hardware that is used for the known algorithms. That is, the calculation speed is increased without requiring increased hardware related costs nor any increases in the size or number of the processors.

The object is according to a second aspect achieved by a device configured to calculate a 10 bits Cyclic Redundancy Check, CRC, value for a message M(x). The device comprises a processor and memory, the memory containing instructions executable by the processor, whereby the device is operative to:
determine the length of the message to be greater than 64 bits,
adapt the message M(x) to have a length of n*128 bits, wherein n is a positive integral number,
fold, n-1 times, of 128 bits by using a PCLMULQDQ instruction comprising performing a carry-less multiplication of two 64-bits operands,
fold of 64 bits by using the PCLMULQDQ instruction, providing a 64 bit message M′(x),

wherein the folding of 128 bits and folding of 64 bits are adapted for use of the PCLMULQDQ instruction to calculate a 10 bit CRC by:
adapting degree of P(x)·K(x) to 32 by setting K(x)=X²², wherein P(x) is a polynomial of degree 10, and wherein·denotes the carry-less multiplication,
performing the folding of 128 bits and folding of 64 bits by [M(x)·x²²]mod[P(x)·x²²],
calculate the 10 bits payload CRC value for the message M(x) by using a CRC-10 table-lookup algorithm.

The object is according to a third aspect achieved by a computer program for a device configured to calculate a 10 bits Cyclic Redundancy Check, CRC, value for a message M(x). The computer program comprises computer program code, which, when run on the device causes the device to:
determine the length of the message to be greater than 64 bits,
adapt the message M(x) to have a length of n*128 bits, wherein n is a positive integral number,
fold, n-1 times, of 128 bits by using a PCLMULQDQ instruction comprising performing a carry-less multiplication of two 64-bits operands,
fold of 64 bits by using the PCLMULQDQ instruction, providing a 64 bit message M′(x),

wherein the folding of 128 bits and folding of 64 bits are adapted for use of the PCLMULQDQ instruction to calculate a 10 bit CRC by:
adapting degree of P(x)·K(x) to 32 by setting K(x)=X²², wherein P(x) is a polynomial of degree 10, and wherein·denotes the carry-less multiplication,
performing the folding of 128 bits and folding of 64 bits by [M(x)·x²²]mod[P(x)·x²²],
calculate the 10 bits payload CRC value for the message M(x) by using a CRC-10 table-lookup algorithm.

The object is according to a fourth aspect achieved by a computer program product comprising a computer program as above, and a computer readable means on which the computer program is stored.

Further features and advantages of the teachings in the present application will become clear upon reading the following description and the accompanying drawings.

### BRIEF DESCRIPTION OF THE DRAWINGS

FIG. 1 illustrates schematically an environment in which embodiments of the present teachings may be implemented.

FIG. 2 illustrates eMBMS end-to-end protocol stack.

FIG. 3 illustrates the format of a SYNC PDU Type 1 packet.

FIG. 4 illustrates the format of a SYNC PDU Type 3 packet for odd number of packets.

FIG. 5 illustrates the format of a SYNC PDU Type 3 packet for even number of packets.

FIG. 6 illustrates an example of a CRC-10 table-lookup algorithm.

FIG. 7 illustrates a message M(x) consisting of two sub-messages.

FIG. 8 illustrates a message M(x) consisting of three sub-messages.

FIG. 9 illustrates a carry-less multiplication.

FIG. 10 illustrates folding of a 128 bit data chunk.

FIG. 11 is a table showing pseudo-code for folding of a 128 bit data chunk.

FIG. 12 illustrates padding of zero bytes.

FIG. 13 illustrates folding of a 64 bit data chunk.

FIG. 14 illustrates a flowchart of an embodiment of the present teachings.

FIGS. 15 and 16 illustrate aspects of memory allocation.

FIG. 17 is a table exemplifying an aligned memory allocation function.

FIG. 18 is a flow chart illustrating steps of a method for calculating 10-bit CRC.

FIG. 19 illustrates means for implementing various embodiments of the method according to the present teachings.

FIG. 20 illustrates a computer program product comprising functions modules/software modules for implementing method of FIG. 18.

FIG. 21 illustrates an exemplary device configured to calculate a 10 bits Cyclic Redundancy Check, CRC, value for a message M(x).

### DETAILED DESCRIPTION

In the following description, for purposes of explanation and not limitation, specific details are set forth such as particular architectures, interfaces, techniques, etc. in order to provide a thorough understanding. In other instances, detailed descriptions of well-known devices, circuits, and methods are omitted so as not to obscure the description with unnecessary detail. Same reference numerals refer to same or similar elements throughout the description.

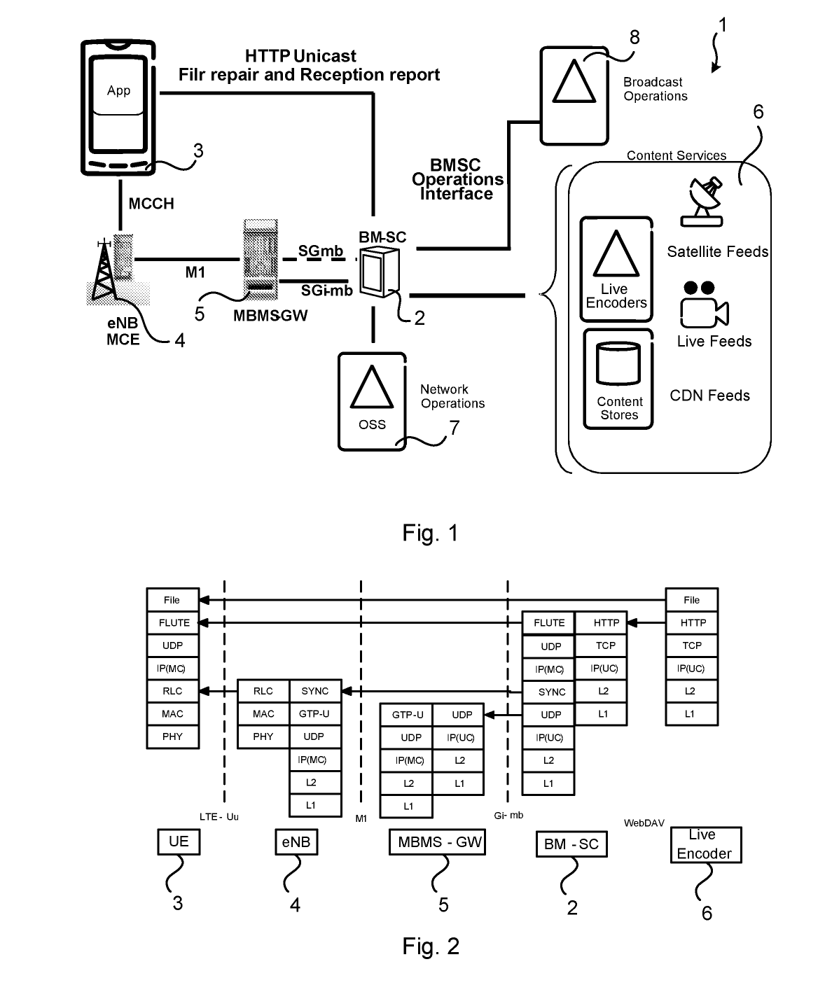

Referring again to FIG. 1, Enhanced MBMS (eMBMS) denotes a MBMS service in evolved packet systems, for example using E-UTRAN (LTE) and UTRAN access. FIG. 2 illustrates an end-to-end protocol stack for the eMBMS. M1 interface is associated to MBMS data (user plane) and uses an Internet Protocol (IP) multicast protocol for delivering packets to eNBs 4. eMBMS, MBMS Synchronization protocol (SYNC-protocol) is specified in 3GPP TS 25.446, and is located in the user plane of the radio network layer over the M1 interface. SYNC packets conveyed according to the MBMS Synchronization protocol uses CRCs. Based on parameters in a header of the SYNC packet, e.g. time stamp or packet number, each eNB 4 is able to derive a timing for downlink radio transmission to the wireless device 3. By using CRC the eNB 4 is able to detect if any SYNC packets are lost during transmission from the BM-SC 2 to the eNB 4.

In each synchronization sequence, the BM-SC 2 sends as a last SYNC packet data unit (PDU) a SYNC PDU without user data but with information about the amount of data that has been sent during the synchronization sequence. This is used by the eNB 4 for detecting the above mentioned possible packet loss(es).

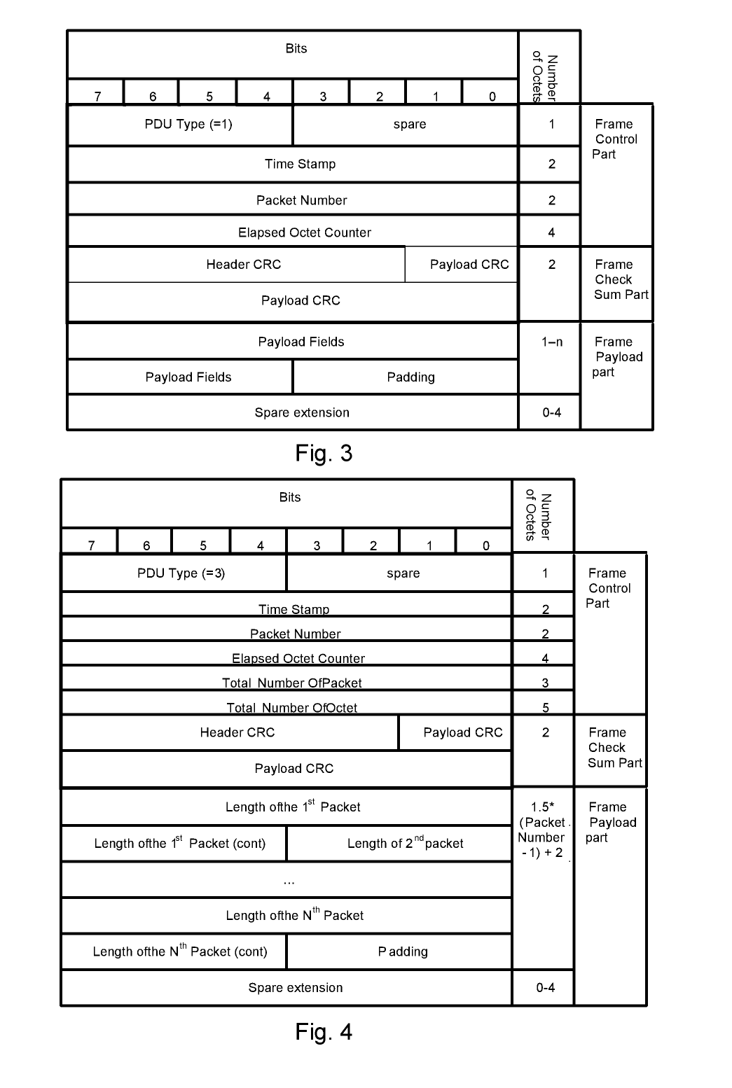

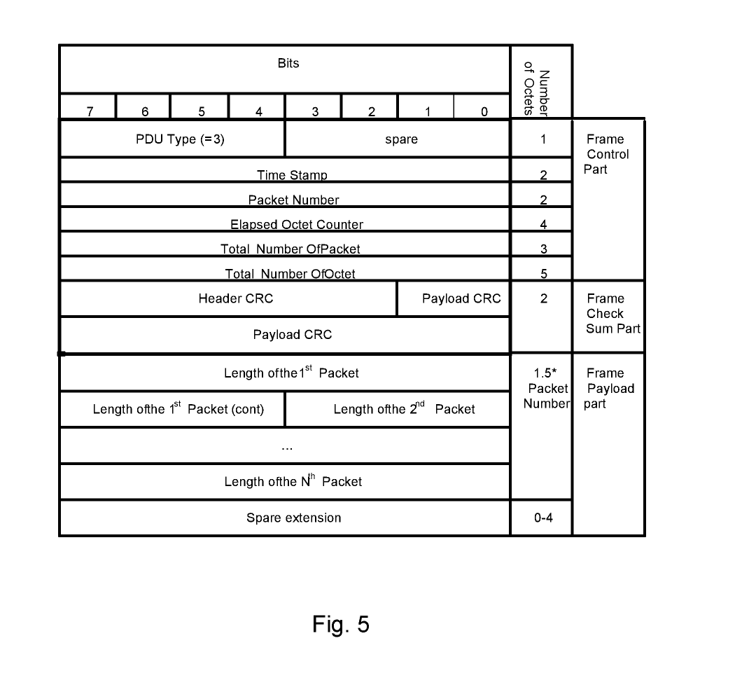

3GPP TS 25.446 defines four different SYNC PDU types, of which the eMBMS uses type 1 and type 3. FIGS. 3, 4 and 5 illustrate these SYNC packet types, and in the figures the SYNC packet headers (also denoted SYNC header in the following) are indicated surrounded by bold lines.

The last SYNC PDU, used by the eNB 4 for detecting packet loss(es), may be repeated to improve the reliability of the delivery to the eNB 4. The number of SYNC PDUs may become substantial and thus also the number of CRC calculations. The payload CRC comprises 10 bits, hence CRC-10 (refer to FIGS. 3, 4 and 5), and the computation of the payload CRC consumes a vast amount of processor time.

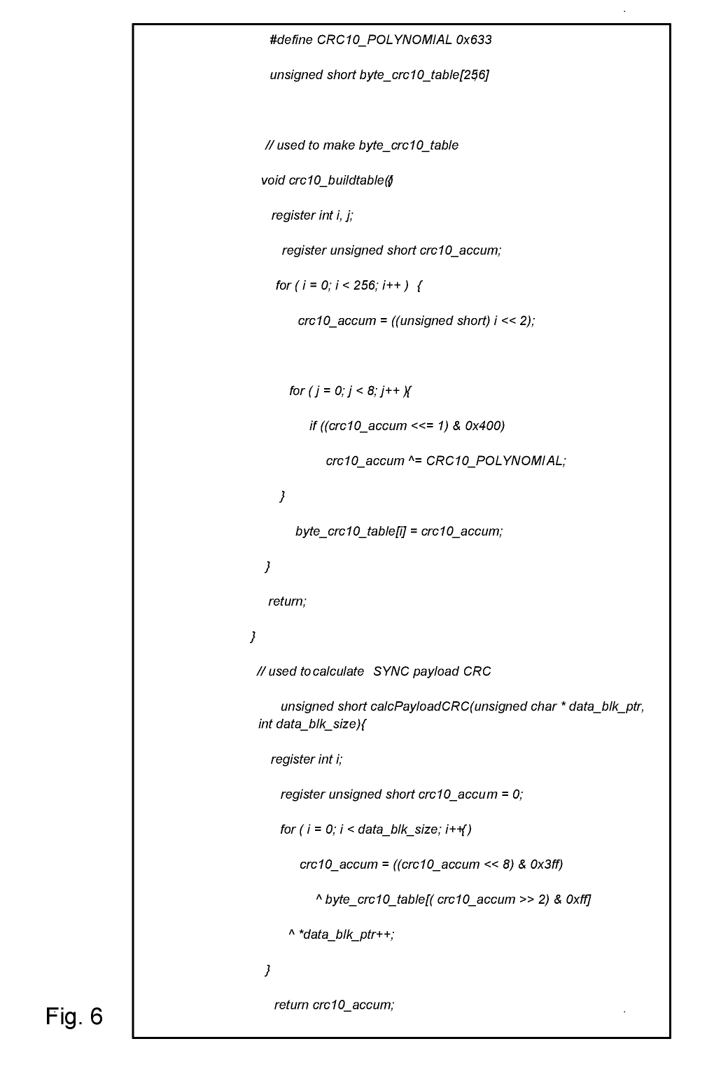

As mentioned in the background section, one way of computing CRC-10 is to implement a table-lookup algorithm, refer for example to FIG. 6 for an example of such an algorithm implemented in C language. The function crc10_buildtable is used to initialize the byte_crc10_table and only needs to be called once at the beginning. The example of FIG. 6 further comprises an exemplary function used for calculating SYNC payload CRC. Although such CRC-10 table-lookup algorithm is fast, the CRC-10 table-lookup algorithm is still the largest consumer of CPU time in the BM-SC 2. The present teachings provide improvements in this regards.

In order to provide proper understanding and appreciation for the teachings of the present application, some theoretical aspects are initially described. In particular, carry-less multiplication, cyclic redundancy check, some theorems of binary polynomial, CPU PCLMULQDQ instruction and folding of a 128-bit data chunk are first described in the following.

Carry-Less Multiplication for Binary Polynomial

Every message M(x) can be represented by a binary polynomial M(x)=aₙXⁿ+aₙ₋₁Xⁿ⁻¹+ . . . +a₁X¹+a₀X⁰, aₙ, aₙ₋₁, . . . , a₀ can only be 0 or 1, degree(M(x))=n if aₙ is not 0.

For example, for message 1011b M(x) is X³+X+1 and have degree(M(x))=3.

In the following, “·” is used to denote a carry-less multiplication for binary polynomial. For example, if there are two binary polynomials M₁(x)=X²+X and M₂(x)=X+1, then

M₁(x)·M₂(x)=(X²+X)·(X+1)=X³+2X²+X≡X³+X. Here the operator “≡” is used for denoting equivalent.

Cyclic Redundancy Check

As mentioned, a cyclic redundancy check (CRC) is an error-detecting code commonly used in digital networks to detect accidental changes to raw data. Blocks of data entering these networks get a short check value attached, based on the remainder of a polynomial division of their contents. That is, a message M(x) input to an encoder will be output as a code word cᵢ=Mᵢ(x) P(x). On retrieval the calculation is repeated, and corrective action can be taken against presumed data corruption if the check values do not match.

The CRC of message M(x) can be defined as:

CRC(M(x))=[X^{degree(P(x)})·M(x)]mod P(x)

P(x), often denoted generator polynomial, is another binary polynomial which defines the CRC algorithm. In some more detail, in a cyclic code, the code word polynomials are multiples of the generator polynomial P(x). The generator polynomial P(x) is chosen to be a divisor of xⁿ+1 so that a cyclic shift of a code vector yields another code vector. A message polynomial mᵢ(x) can be mapped to a code word polynomial cᵢ(x)=mᵢ(x) x^{n-k}−rᵢ(x)(i=0, 1, . . . , 2^{k-1}−1), where rᵢ(x) is the reminder of the division of mᵢ(x) x^{n-k} by P(x).

For CRC-10 used in SYNC, P(x)=x¹⁰+x⁹+x⁵+x⁴+x+1, so CRC-10 (M(x))=[X¹⁰·M(x) ]mod (x¹⁰+x⁹+x⁵+x⁴+x+1) .

Some Theorems of Binary Polynomial

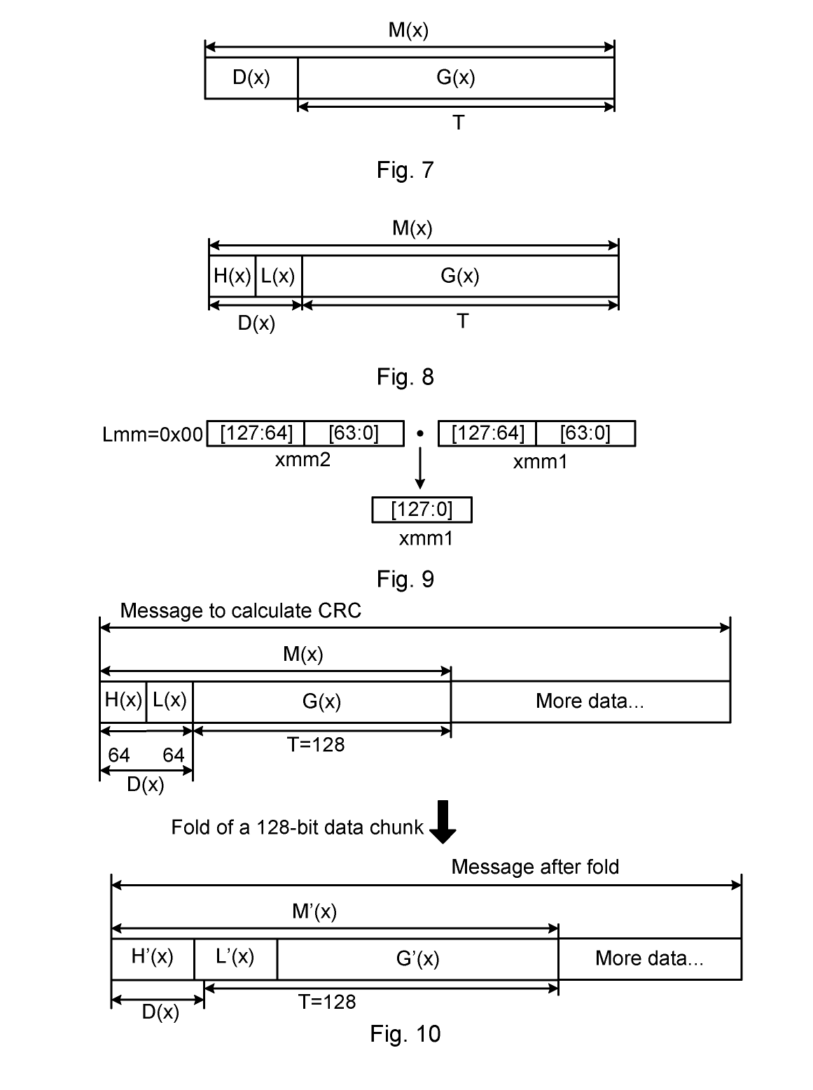

Referring to FIG. 7, message M(x) consists of two sub-messages D(x) and G(x). If the length of sub-message G(x) is T, then:

M(x)=(D(x)·X^{T})xor G(x) eq. (1)

If T>=degree(P(x)), then:

CRC(M(x))=M(x)mod P(x)≡{D(x)·[x^{T} mod P(x)] xor G(x)} mod P(x) eq. (2)

In FIG. 8, assume D(x) consists of two sub-messages H(x) and L(x). Then message M(x) consists of three sub-messages H(x), L(x) and G(x).

The length of both H(x) and L(x) is 64 bits. If the length of sub-message G(x) is T and T>=128 bits, then:

D(x)·[x^{T} mod P(x)]≡{H(x)·[x^{(T+64)} mod P(x)]} xor {L(x)·[x^{T} mod P(x)]} eq. (3)

CRC(M(x))=M(x) mod P(x)≡{H(x)·[x^{(T+64)} mod P(x)]} xor {L(x)·[x^{T}mod P(x)]}xor G(x) mod P(x) eq. (4)

Defining K₁=[x^{(T+64)} mod P(x)]and K₂=[x^{T} mod P(x)], both K₁ and K₂ are constants and they can thus be pre-calculated.

CPU PCLMULQDQ Instruction

A PCLMULQDQ instruction in a processor performs carry-less multiplication of two 64-bit quadwords (8-byte) which are selected from the first and the second operands according to the immediate byte value.

The PCLMULQDQ instruction format is as below:
PCLMULQDQ xmm1, xmm2, imm8

And it can be presented by carry-less multiplication:

xmm1=xmm2·xmm1

A carry-less multiplication of one quadword (8-byte) of xmm1 by one quadword (8-byte) of xmm2, returns double quadwords (16 bytes). The immediate byte (imm8) is used for determining which quadwords of xmm1 and xmm2 should be used. Due to the nature of carry-less multiplication, the most-significant bit of the result will be 0.

The immediate byte values are used as follows:

| imm[7:0] | Operation |
|---|---|
| 0x00 | xmm2/m128[63:0] · xmm1[63:0] |
| 0x01 | xmm2/m128[63:0] · xmm1[127:64] |
| 0x10 | xmm2/m128[127:64] · xmm1[63:0] |
| 0x11 | xmm2/m128[127:64] · xmm1[127:64] |

For example, if imm8=0, the carry-less multiplication for xmm1 and xmm2 is as illustrated in FIG. 9. In particular, imm8=0x00, then from the above table, xmm2 m128[63:0]·xmm1[63:0]. xmm1 and xmm2 are two 128 bits processor registers which support Streaming SIMD Extensions (SSE) instructions, wherein SIMD stands for Single instruction, multiple data. xmm1 and xmm2 hold 64 bits of data in their low 64 bits (0˜−63) (no data in their high 64 bits) before the carry-less multiplication. After the carry-less multiplication, the resulting data will become 128 bits of length and be put in xmm1 register.

Fold of a 128-Bit Data Chunk

For any application that requires CRC, a few constants can be pre-computed and then these constants can be repeatedly applied to fold the most-significant chunks of the message, at each stage creating a new message that is smaller in length but congruent (modulo the polynomial) to the original one, as illustrated in FIG. 10.

In FIG. 10, the message for which a CRC is to be calculated comprises message M(x) and more data. The message M(x) comprises two adjacent chunks of data of length 128 bits, D(x) and G(x). M(x) of the message, M(x)+more data, is the most-significant chunk of data and is folded into an adjacent chunk of the same size, thus reducing the required data buffer length by the length of the adjacent chunk. This is illustrated in FIG. 10, in that the total length of the message after folding is reduced. The most-significant chunks of the data buffer is thus folded providing a data buffer (M′(x)) smaller in length cut congruent to the original one (M(x)).

In more detail and still with reference to FIG. 10: in order to use PCLMULQDQ Instruction more efficiently, the data should be repeatedly folded down by 128 bits at a time. If the length of H(x) and L(x) are set to be 64 bits, T is 128 bits, degree(P(x))=32, then according to formula (4), K1=[x^{(T+64)} mod P(x)]=[x⁽¹²⁸⁺⁶⁾ mod P(x)] is 32 bits, K2=[x^{T} mod P(x)]=[x¹²⁸ mod P(x)]is 32 bits and:

D′(x)={H(x)·[x^{(T+64)} mod P(x)]} xor {L(x)·[x^{T} mod P(x)]} xor G(x)=)={H(x)·K₁} xor {L(x)·K₂} xor G(x)

After a single folding of 128-bit data chunk, the length of message for which to calculate a CRC is reduced by 128 bits, but the CRC of the message after folding keeps congruent with the initial message. Because degree of (P(x))=32, the CRC-32 value of the message is calculated according to P(x).

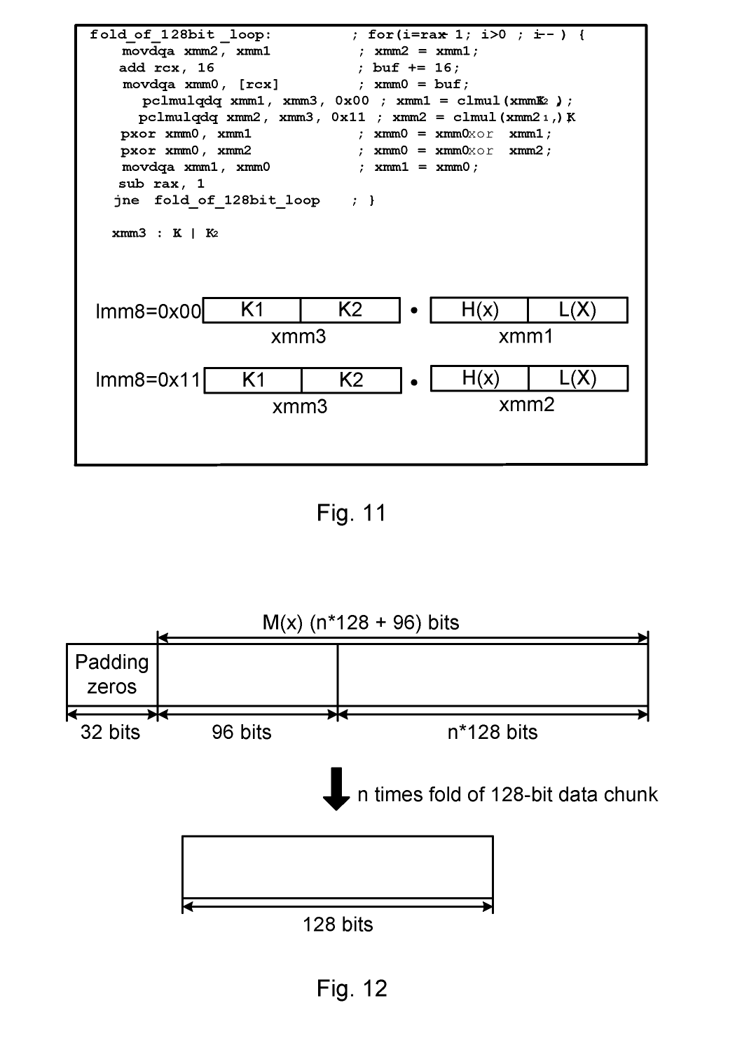

FIG. 11 illustrates an exemplary pseudo-code for the above described folding of a 128-bit data chunk.

Padding Zero Bytes

If the above method of folding a 128-bit data chunk is repeatedly applied to a message, a message of any length can be folded to finally obtain a 128-bits message. For messages the length of which cannot be divided by 128 exactly, padding of some zero bytes can be done at the beginning of the message.

FIG. 12 illustrates an example of such padding of zero bytes. In particular, the message M(x) comprises (n*128+96) bits, i.e. not exactly dividable by 128. Therefore, padding 8 zero bytes, i.e. 32 zero bits, gives the message M(x) the length (n+1)*128, which thus makes the length of the message to be dividable by 128.

Fold of a 64-Bit Data Chunk

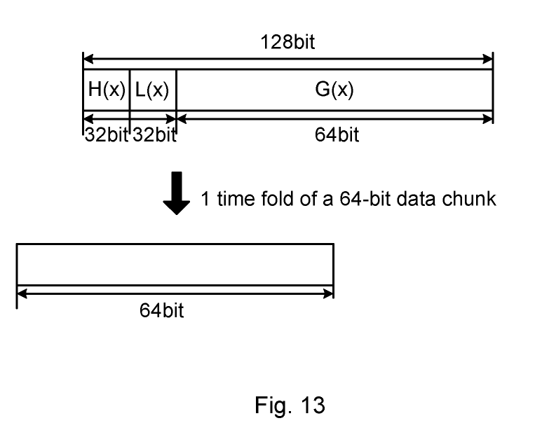

Using the same theory as for folding of a 128-bit data chunk, according to eq. 5 below, a 128 bits message can be folded to a 64 bit message as shown in FIG. 13. For the purposes of embodiments that will be described below, after having obtained a 128 bits message this 64 bits folding algorithm need to be called only once to generate a 64 bits message.

CRC-32(M(x))≡{H(x)·[x^{(64+32)]}mod P(x)} xor {L(x)·[x⁶⁴ mod P(x)]} xor G(x) mod P(x) eq. (5)

In eq. (5), K₃=x⁽⁶⁴⁺³²⁾ mod P(x) and K4=x⁶⁴ mod P(x) are constants and can be pre-computed.

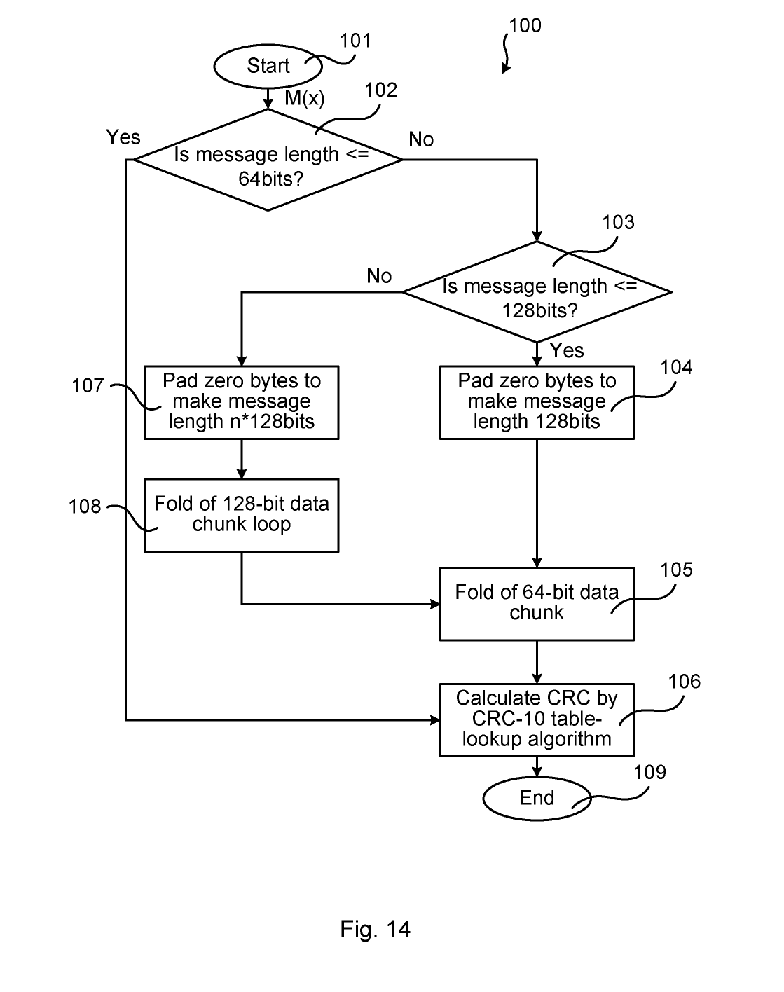

FIG. 14 illustrates a flowchart of an embodiment of the present teachings. The method 100 starts in box 101, by inputting a message M(x) for which a CRC-10 calculation is to be performed. The message M(x) may for example be a SYNC packet of type 1 or of type 3 of Synchronization protocol, e.g. as specified in 3GPP TS 25.446, wherein the SYNC packet comprises the payload of an User Datagram Protocol, UDP, packet. It is noted that other messages may benefit from the teachings of the present application, for which messages a CRC-10 calculation is needed.

Next, in box 101 it is determined whether the bit length of the message is greater than 64 bits or if it is smaller or equal to 64 bits. This can be done any conventional way, for example by obtaining the message length from a field of the packet and making a comparison, i.e. checking if the length of the SYNC packet payload is less than or equal to 8 bytes.

For messages that are shorter than or equal to 64 bits, a CRC-10 table-lookup algorithm may be used directly. That is, if, in box 101, it is determined that the message length is less than or equal to 64 bits, the method 100 continues directly to box 106, wherein the CRC for the input message is calculated by using a CRC-10 table-lookup algorithm. One example of such CRC-10 table-lookup algorithm that could be used is the algorithm illustrated in FIG. 6. The method 100 then proceeds to box 109, where the method 100 ends.

For messages that are longer than 64 bits, the method 100 instead proceeds to box 103.

If, in box 103, it is determined that the message length is less than or equal to 128 bits, the method proceeds to box 104. In box 104, padding is performed (if needed) so as to provide a message with a message length of 128 bytes. If the message length is equal to 128 bits, then no padding is needed and the same message as input to box 103 is output. If the message is less than 128 bits then padding is performed. In the padding, additional bytes are appended at the end of the message, the additional bytes typically being zero bytes (i.e. all bits taking value 0). Such zero padding expands the data of the message to 128 bits and the output of box 104 is thus a message of length 128 bits.

It is noted that three different results may be identified from the length determination of box 103: greater than 128 bits, equal to 128 bits and smaller than 128 bits. For the case that the message length is equal to 128 bits, an additional branch could have been illustrated, starting at box 103 and ending in box 105, since no padding is needed.

If, in box 103, it is determined that the message length is greater than 128 bits, the method proceeds to box 107. In box 107, zero bytes are padded to make the message length an integer multiple of 128 bits, i.e. n*128 bits. The output from box 107 is thus a message with length n*128 bits, wherein n is a positive integer.

From box 107, the flow continues to box 108, wherein the message of length n*128 bits output from box 107 is folded (n-1) times giving as output a message of length 128 bits. That is, the message of length n*128 bits input to box 108 is folded in a loop, i.e. the folding of 128 bits is performed repeatedly until the result is a message of length 128 bits.

The method 100 then proceeds to box 105, into which a message of length 128 bits is thus input. In box 105, the 128 bits message is folded providing a message of length 64 bits. The output of box 105 is thus a message M′(x) having a message length of 64 bits.

Next, the method 100 proceeds to box 106, wherein a CRC-10 table-lookup algorithm is applied to calculate the 10 bits CRC of the message input to box 101. The CRC-10 table-lookup algorithm that is used can be chosen based on the application at hand.

The folding, in box 108, of 128 bits and the folding, in box 105, of 64 bits are adapted for use of the PCLMULQDQ instruction to calculate a 10 bit CRC, which adaptation will be described next.

In order to take advantage of the PCLMULQDQ carry-less multiplication instruction, a generator polynomial P(X) of degree 32 is needed. That is, some aspects of the methods described thus far need to be extended and adapted for CRC-10 calculation.

From CRC(M(x))=[X^{degree(P(x))}·M(x) mod P(x)], :

CRC(M(x))·K(x)=[X^{degree(P(x))}·M(x)·K(x)] mod [P(x)·K(x)] Eq. (6)

For CRC-10 in SYNC protocol, P(x)=x¹⁰+x⁹+x⁵+x⁴+x+1. In order to take advantage of the PCLMULQDQ carry-less multiplication instruction in the 128-bit folding and the 64-bit folding, the degree of P(x)·K(x) needs to be 32 bits. Therefore, in Eq. 6, let K(x)=X²² and then:

CRC-10 (M(x))·K(x)=[M(x) mod P(x)]·K(x)≡[M(x)·X²²]mod [P(x)·X²²] (7)

Then a folding of 128-bit data chunk and fold of 64-bit data chunk is applied to message M(x) by using P′(x)=P(x)·x²²==(x³²+x³¹+x²⁷+x²⁶+x²³+x²²)=0x018CC00000 which is a 32 bits binary polynomial.

Then setting K1′={x⁽¹²⁸⁺⁶⁴⁾ mod P′(x)}0x92c00000, K2′=[x¹²⁸ mod P′(x)]=0xfb000000, K3′=x⁽⁶⁴⁺²²⁾ mod P′(x)=0xa8000000 and K4′=x⁶⁴mod P′(x) =0xb2400000.

If M′(x) is used to denote the final 64 bit message after applying fold of 128-bit data chunk and fold of 64-bit data chunk, this will result in:

CRC-10(M(x))·K(x)=[X^{degree(P(x))}·M′(x)·X²²] mod [P(x)·X²²] (8)

CRC-10(M(x))·K(x) gives a CRC-32 result and to get the desired CRC-10 result, there is no need to calculate the value of [M′(x)·X²²] mod [P(x)·X²²]. In fact, the following equation may be concluded from equation (8)

CRC-10(M(x))≡[X^{degree(P(x))}·M′(x)]mod P(x) (9)

Equation (9) is a CRC-10 calculation, and a CRC-10 table-lookup algorithm may be applied to calculate the CRC-10 value of the final 64 bit (i.e. 8 bytes) message M′(x).

Applying the teachings above improves the performance of a network node, e.g. the BM-SC, to support more concurrent delivery sessions and higher bitrate traffic. By the described optimization of the payload CRC computation adapted for SYNC packets, a faster CRC-10 algorithm is provided. The new CRC-10 algorithm is based on folding of a 128-bit data chunk and folding of a 64-bit data chunk by using PCLMULQDQ instruction reducing the length of a message quickly and keep its CRC-10 value same.

The faster CRC-10 algorithm thus results from enabling the use of PCLMULQDQ instructions, and it can be shown that it is many times faster than the currently used CRC-10 table-lookup algorithm. Testing for 1 million SYNC packets were done in a BM-SC, wherein the payload length of the SYNC packets was 1300 bytes. When using the new CRC-10 algorithm, the BM-SC was shown to be able to support much more concurrent delivery sessions and higher bitrate traffic with same hardware, i.e. without the need to add e.g. further processors. The CPU usage for calculating the payload of SYNC packets is greatly reduced and the BM-SC can support much more concurrent delivery sessions and higher bitrate traffic with same hardware.

In the embodiments to be described below, the fact that look-up table algorithms require vast memory resources is addressed and improved. In particular, embodiments comprising memory alignment for the CRC-10 fast computation algorithm is described next.

The following description uses well known basic types used in computer programming language, e.g. “char” which is an integer type and is the smallest addressable unit of a machine that can contain basic character set, and “movdqu” (move of double quadword unaligned) which is an instruction storing selected bytes from the source operand (first operand) into a 128-bit memory location. Further such instructions are used below to describe embodiments, and for further types used in computer programming language, reference is made to reference literature relating to basic programming language.

There are two instructions which can be used to load 16 bytes (double quadword) data to 128 bits XMM register one time: movdqa and movdqu like below (rcx register has the address of data):

movdqa xmm0, [rcx]

movdqu xmm0, [rcx]

“movdqa” is typically much faster than “movdqu”, but when the source or destination operand of “movdqa” is a memory operand, the operand must be aligned on a 16-byte boundary or else a general-protection exception will be generated. “movdqu” has no such memory alignment requirement.

In order to make the earlier described CRC-10 computation algorithm yet still faster, “movdqa” is used to load SYNC packet payload for CRC-10 (see FIG. 11).

Assume that the header length of SYNC packet is m. For SYNC type 3 packet, m=19 bytes; for SYNC type 1, m=11 bytes. If it is assumed that the payload length of SYNC packet is n and k zero bytes have to be padded such that to make (n+k) can be divided by 16 exactly, then:

k=(16−n)mod 16 (assume n mod 16>0)

Because a SYNC packet is sent by UDP, the whole SYNC packet is the payload of UDP packet. Therefore, a memory allocation method for UDP payload is provided in order to ensure 16 bytes memory alignment for the SYNC packet payload, taking into consideration the zero bytes padding.

Because the length k (0<k<=15) of padding zero bytes may be bigger than SYNC packet header length which may be 11 for SYNC type 1 packet, there are two cases:

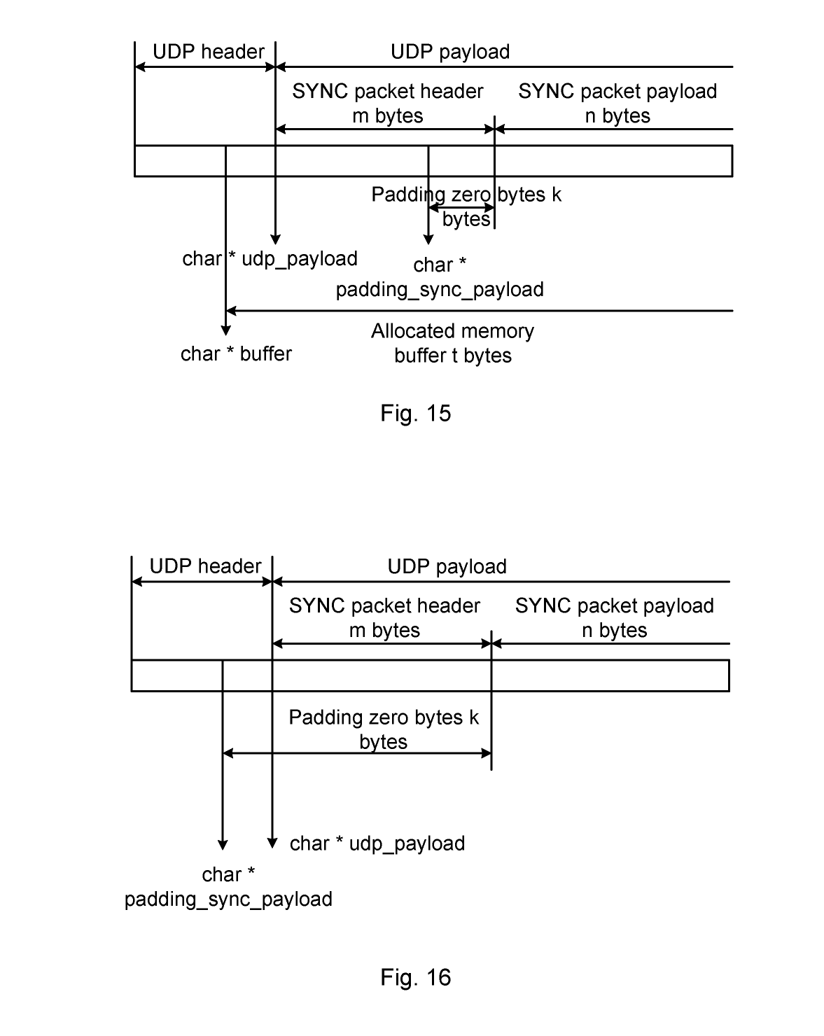

1) k<=m as illustrated in FIG. 15, and

2) k>m as illustrated in FIG. 16.

For the two cases, there is a need to allocate memory to ensure that the address “char *padding_sync_payload” is in indeed in 16 bytes memory alignment. padding_sync_payload is the starting address of SYNC payload to calculate CRC-10 in accordance with the various embodiments of the method as described.

For the first case, k<=m, the allocated memory:

char*buffer=alignedMemAlloc (t, 16);

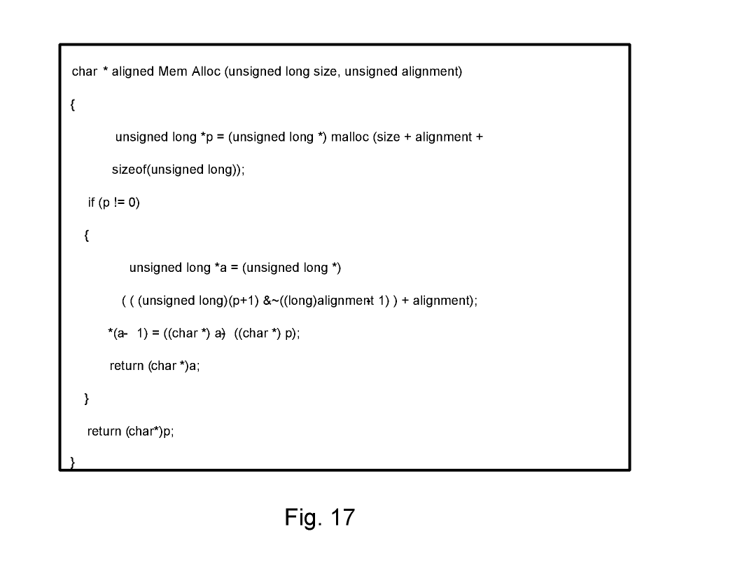

t is the length of memory buffer to be allocated and 16 means 16 bytes alignment. alignedMemAlloc is a function to allocate a chunk of memory with required alignment, refer to FIG. 17, wherein such an aligned memory allocation function is exemplified. Now:

t=(m+n)+16−(m+n)mod 16; (assume (m+n)mod 16>0)

char*udp_payload=buffer+t−(m+n)mod 16;

char*padding_sync_payload=udp_payload+m;

, wherein udp payload is the starting address of UDP payload to hold the SYNC packet.

The above can be used for embodiments of the method 100 as described with reference to FIG. 14 for ensuring aligned memory allocation. In particular, in an embodiment of the method according to the teachings in relation to FIG. 14, padding may be performed, the padding comprising, for k less than or equal to m, padding zero bytes within the UDP payload.

Further, for k less than or equal to m, the allocating may comprise allocating a memory buffer of length t in the memory 36 (refer to FIG. 19), wherein the starting address of the UDP payload to hold the SYNC packet is determined by:
determining the size t of the aligned memory buffer to be (m+n)+16−[(m+n)mod16], and
determining the starting address of the UDP payload to be starting address of the memory buffer+t−[(m+n)mod16].

The starting address of the SYNC packet payload comprises the starting address of the UDP payload+m.

For the second case, k>m, the allocated memory:

char*buffer=alignedMemAlloc (i t, 16);

t=k+n;

char*padding_sync_payload=buffer;

char*udp_payload=buffer+(k−m);

In the method 100 as described in relation to FIG. 14, aligned memory allocation can be ensured also for the case of k being greater than m. Padding may be performed comprising, for k greater than m, padding zero bytes within the UDP header.

Further, for k greater than m, the allocating may comprise allocating a memory buffer of length t in the memory 36, wherein the starting address of the UDP payload to hold the SYNC packet is determined by:
determining the size t of the aligned memory buffer to be k+n, and
determining the starting address of the UDP payload to be starting address of the memory buffer+(k−m).

The address of the SYNC packet payload comprises the starting address of the memory buffer.

After allocating the memory buffer, the below steps may be performed to fill the SYNC packet content:

1) Fill memory buffer with zero bytes

2) Read SYNC packet payload to char*sync_payload=padding_sync_payload+k;

3) Calculate the CRC-10 of SYNC packet payload

4) Fill SYNC packet header

5) Send SYNC packet as UDP payload

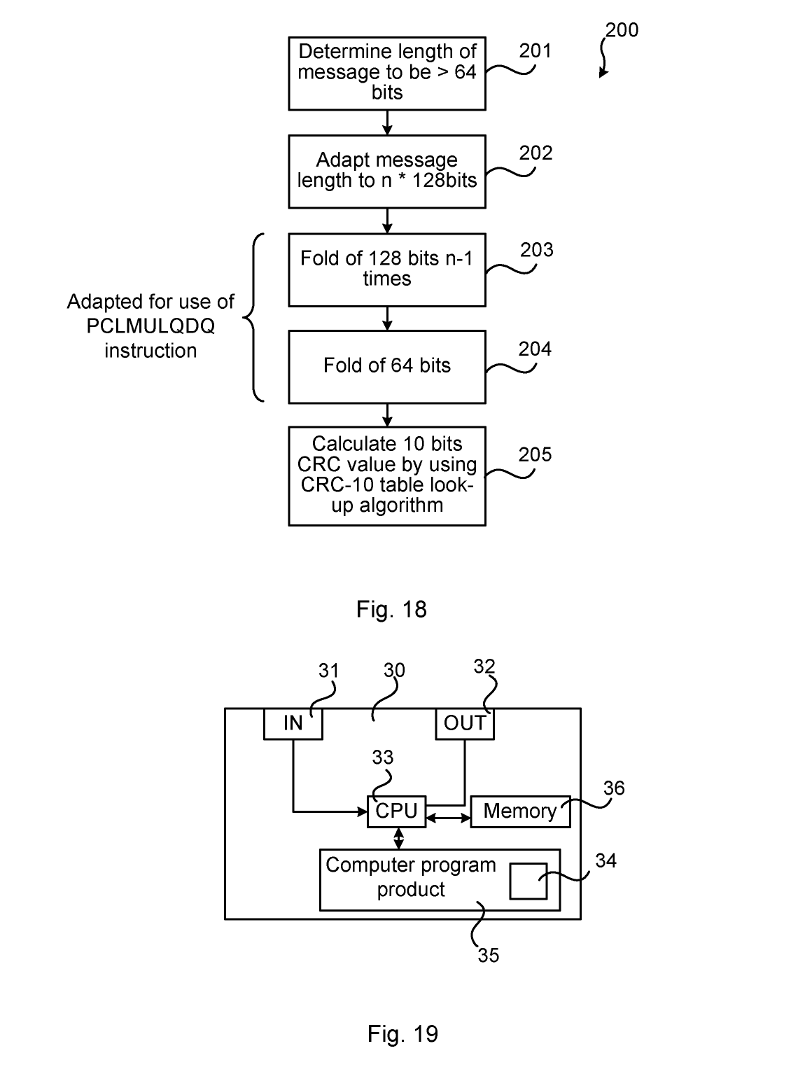

FIG. 18 is a flow chart illustrating steps of a method 200 for calculating 10-bit CRC based on the above description. The method 200 may be implemented in a processor 33 (refer to FIG. 19). In particular, the method 200 for calculating a 10 bits Cyclic Redundancy Check, CRC, value for a message M(x) comprises determining 201 the length of the message M(x) to be greater than 64 bits (compare box 102 of FIG. 14 and related description).

Next, the message M(x) is adapted 202 to have a length of n*128 bits, wherein n is a positive integral number (compare boxes 104 and 107 of FIG. 14 and related description).

Next, a folding 203 of 128 bits is performed n-1 times, by using a PCLMULQDQ instruction comprising performing a carry-less multiplication of two 64-bits operands (compare boxes 107 and 108 of FIG. 14 and related description). Referring also to FIG. 14, if the message M(x) thus has a length of less than or equal to 128 bits (as determined in box 103), the message is adapted to have a length of 128 bits (box 104), then n=1 and the folding 203 of 128 bits is performed zero times.

Next, folding 204 of 64 bits is done by using the PCLMULQDQ instruction, providing a 64 bit message M′(x) (compare box 105 of FIG. 14 and related description).

The folding steps above, i.e. the folding 203 of 128 bits and the folding 204 of 64 bits, are adapted for use of the PCLMULQDQ instruction to calculate a 10 bit CRC by:
adapting the degree of P(x)·K(x) to 32 by setting K(x)=X²², wherein P(x) is a polynomial of degree 10, and wherein·denotes the carry-less multiplication,
performing the folding of 128 bits and folding of 64 bits by [M(x)·x²²]mod[P(x)·x²²].

Next, the 10 bits payload CRC value is calculated 205 for the message M(x) by using a CRC-10 table-lookup algorithm.

In another embodiment of the above method, the message M(x) comprises a SYNC packet of type 1 or type 3 of Synchronization protocol, wherein the SYNC packet comprises the payload of an User Datagram Protocol, UDP, packet, the SYNC packet comprising a header of m bytes and a payload of n bytes, m=11 for SYNC packet of type 1 and m=19 for SYNC packet of type 3, the UDP packet comprising a UDP header and a UDP payload. In this embodiment, the method 200 further comprises performing, before the step of determining 201:
padding zero bytes of length k so as to adapt the sum of the SYNC packet payload length n and the k zero bytes to be a multiple of 16,
allocating memory 36 accessible by the processor 30, 32, in which the method 200 is implemented, so as to ensure a starting address of the SYNC packet payload to have a 16 bytes memory alignment.

In a variation of the above embodiment, the padding comprises, for k less than or equal to m, padding zero bytes within the UDP payload.

In a variation of the above embodiment, for k less than or equal to m, the allocating comprises allocating a memory buffer of length t in the memory 36, wherein the starting address of the UDP payload to hold the SYNC packet is determined by:
determining the size t of the aligned memory buffer to be (m+n)+16−[(m+n)mod16], and
determining the starting address of the UDP payload to be starting address of the memory buffer+t−[(m+n)mod16].

In a variation of the above embodiment, the starting address of the SYNC packet payload comprises the starting address of the UDP payload+m.

In another embodiment, the padding comprises, for k greater than m, padding zero bytes within the UDP header.

In a variation of the above embodiment, for k greater than m, the allocating comprises allocating a memory buffer of length t in the memory 36, wherein the starting address of the UDP payload to hold the SYNC packet is determined by:
determining the size t of the aligned memory buffer to be k+n, and
determining the starting address of the UDP payload to be starting address of the memory buffer+(k−m).

In a variation of the above embodiment, the starting address of the SYNC packet payload comprises the starting address of the memory buffer.

In an embodiment, the method further comprises:
filling the memory buffer with zero bytes,
reading the payload of the SYNC packet to the starting address for the SYNC packet payload, and
performing steps 201 through 205.

In an embodiment, the message M(x) comprises a SYNC packet according to Multimedia Broadcast and Multicast Services, MBMS, Synchronization protocol or according to enhanced Multimedia Broadcast and Multicast Services, eMBMS, Synchronization protocol.

In an embodiment, in the determining 201, the length of the message is determined to be less than 128, and the adapting 202 comprises padding zero bytes to make the message length 128 bits.

In still another embodiment, in the determining 201, the length of the message is determined to be greater than 128 bits, and the adapting 202 comprises padding zero bytes to make the message length n*128 bits.

In an embodiment, the generator polynomial P(x)=x¹⁰x⁹+x⁵+x⁴+x+1, and P′(x)=P(x)·x²²=(x³²+x³¹+x²⁷+x²⁶+x²³+x²²).

In an embodiment, the method comprises, following the folding 203 of 128 bits and folding 204 of 64 bits and prior to calculating 205 the 10 bits payload CRC value:
folding M″(x)=M′(x)·X²², providing a message M″(x) having a length larger than 64 bits,
adapting the length of M″(x) to 128 bits and folding of 64 bits by using the PCLMULQDQ instruction,
performing Barrett's reduction, providing 32 bits CRC, and
shifting the 32 bits CRC 22 bits to the right.

With reference now to FIG. 19, the teachings also encompasses a device 30 configured to calculate a 10 bits Cyclic Redundancy Check, CRC, value for a message M(x). The device 30 comprises a processor 33 and memory 36, the memory 36 containing instructions executable by the processor 33, whereby the device 30 is operative to perform the steps of the various methods that have been described. In a particular embodiment, the device 30 is operative to:
determine the length of the message to be greater than 64 bits,
adapt the message M(x) to have a length of n*128 bits, wherein n is a positive integral number,
fold, n-1 times, of 128 bits by using a PCLMULQDQ instruction comprising performing a carry-less multiplication of two 64-bits operands,
fold of 64 bits by using the PCLMULQDQ instruction, providing a 64 bit message M′(x),

wherein the folding of 128 bits and folding of 64 bits are adapted for use of the PCLMULQDQ instruction to calculate a 10 bit CRC by:
adapting degree of P(x)·K(x) to 32 by setting K(x)=X²², wherein P(x) is a polynomial of degree 10, and wherein·denotes the carry-less multiplication,
performing the folding of 128 bits and folding of 64 bits by [M(x)·x²²]mod[P(x)·x²²],
calculate the 10 bits payload CRC value for the message M(x) by using a CRC-10 table-lookup algorithm.

The teachings of the present application also encompass a computer program 34 for a device 30, as described, configured to calculate a 10 bits Cyclic Redundancy Check, CRC, value for a message M(x). The computer program 34 comprising computer program code, which, when run on the device 30 causes the device 30 to perform steps of the methods as described. In a particular embodiment, the computer program 34 comprising computer program code, which, when run on the device 30 causes the device 30 to perform steps of:
determine the length of the message to be greater than 64 bits,
adapt the message M(x) to have a length of n*128 bits, wherein n is a positive integral number,
fold, n-1 times, of 128 bits by using a PCLMULQDQ instruction comprising performing a carry-less multiplication of two 64-bits operands,
fold of 64 bits by using the PCLMULQDQ instruction, providing a 64 bit message M′(x),

wherein the folding of 128 bits and folding of 64 bits are adapted for use of the PCLMULQDQ instruction to calculate a 10 bit CRC by:
adapting degree of P(x)·K(x) to 32 by setting K(x)=X²², wherein P(x) is a polynomial of degree 10, and wherein·denotes the carry-less multiplication,
performing the folding of 128 bits and folding of 64 bits by [M(x)·x²²]mod[P(x)·x²²],
calculate the 10 bits payload CRC value for the message M(x) by using a CRC-10 table-lookup algorithm.

The teachings of the present application also encompasses a computer program product 35 comprising a computer program 34 as described above, and a computer readable means on which the computer program 34 is stored. The computer program product 35 may be any combination of read and write memory (RAM) or read only memory (ROM). The computer program product 35 may also comprise persistent storage, which for example can be any single one or combination of magnetic memory, optical memory or solid state memory.

The computer program product 35, or the memory 36, thus comprises instructions executable by the processor 30. Such instructions may be comprised in a computer program 34, or in one or more software modules or function modules.

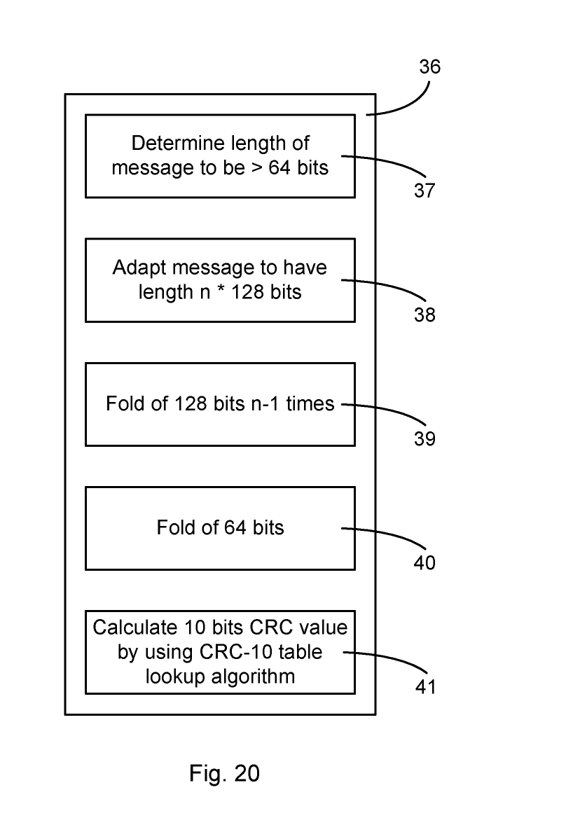

An example of an implementation using functions modules/software modules is illustrated in FIG. 20, in particular illustrating a computer program product comprising functions modules for implementing methods of FIG. 18. The memory 36 comprises means 37, in particular a first function module 37, for determining the length of a message to be greater than 64 bits (compare step 201 of FIG. 18 and box 102 of FIG. 14).

The memory 36 comprises means 38, in particular a second function module 38, for adapting the message M(x) to have a length of n*128 bits, wherein n is a positive integral number (compare step 202 of FIG. 18 and boxes 104, 107 of FIG. 14).

The memory 36 comprises means 39, in particular a third function module 39, for folding, n-1 times, of 128 bits by using a PCLMULQDQ instruction comprising performing a carry-less multiplication of two 64-bits operands.

The memory 36 comprises means 40, in particular a fourth function module 40, for folding of 64 bits by using the PCLMULQDQ instruction, providing a 64 bit message M′(x).

The folding of 128 bits and folding of 64 bits are adapted for use of the PCLMULQDQ instruction to calculate a 10 bit CRC by:
adapting degree of P(x)·K(x) to 32 by setting K(x)=X²², wherein P(x) is a polynomial of degree 10, and wherein·denotes the carry-less multiplication,
performing the folding of 128 bits and folding of 64 bits by [M(x)·x²²]mod[P(x)·x²²]. The third function module 39 and the fourth functions module 40 thus performs their respective folding according to the above adapting of degree and performing of folding.

The memory 36 comprises means 41, in particular a fifth function module 41, for calculating the 10 bits payload CRC value for the message M(x) by using a CRC-10 table-lookup algorithm.

The functional modules can be implemented using software instructions such as computer program executing in a processor and/or using hardware, such as application specific integrated circuits, field programmable gate arrays, discrete logical components etc.

Based on the above, an embodiment of the device 30 may be implemented e.g. comprising the first, second, third, fourth and fifth function modules, the device 30 being configured to calculate a 10 bits Cyclic Redundancy Check, CRC, value for a message M(x). In an embodiment thus, the device 30 comprises:
means, e.g. the first function module 37, for determining the length of a message to be greater than 64 bits,
means, e.g. the second function module 38, for adapting the message M(x) to have a length of n*128 bits, wherein n is a positive integral number,
means, e.g. the third function module 39, for folding, n-1 times, of 128 bits by using a PCLMULQDQ instruction comprising performing a carry-less multiplication of two 64-bits operands,
means, e.g. fourth function module 40, for folding of 64 bits by using the PCLMULQDQ instruction, providing a 64 bit message M′(x),
means, e.g. fifth function module 41, for calculating the 10 bits payload CRC value for the message M(x) by using a CRC-10 table-lookup algorithm.

The means for folding of 128 bits and folding of 64 bits are adapted for use of the PCLMULQDQ instruction to calculate a 10 bit CRC by:
adapting degree of P(x)·K(x) to 32 by setting K(x)=X²², wherein P(x) is a polynomial of degree 10, and wherein·denotes the carry-less multiplication,
performing the folding of 128 bits and folding of 64 bits by [M(x)·x²²]mod[P(x)·x²²].

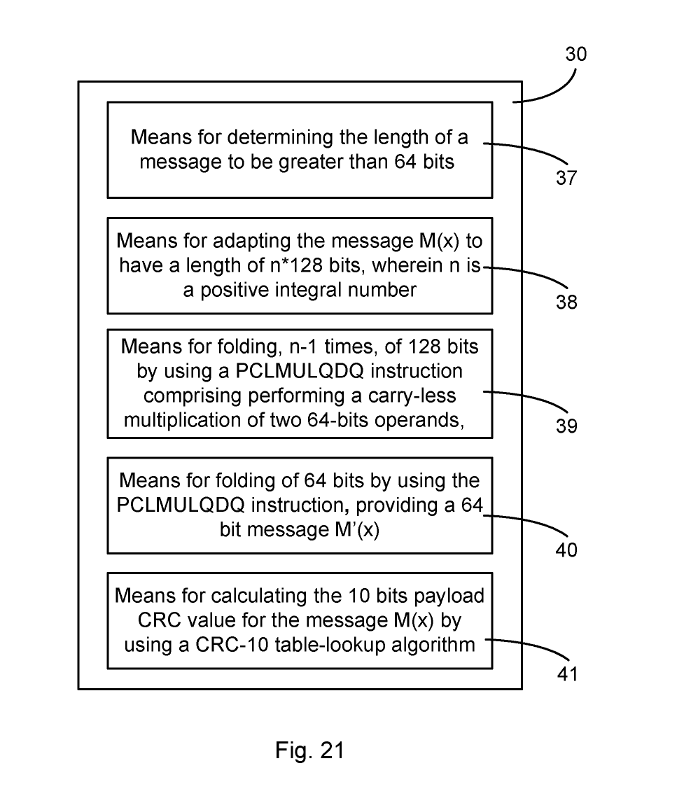

This embodiment is illustrated in FIG. 21, which shows a device 30 comprising the above-mentioned means.

Furthermore, the above mentioned and described embodiments are only given as examples and should not be construed as limiting to the present invention. Other solutions, uses, objectives, and functions within the scope of the invention as claimed in the accompanying patent claims should be apparent for the person skilled in the art.

1-31. (canceled)

32. A method performed in a processor for calculating a 10-bit Cyclic Redundancy Check (CRC) value for a message M(x), the method comprising:
determining length of the message to be greater than 64 bits;
adapting the message M(x) to have a length of n*128 bits, wherein n is a positive integral number;
folding n-1 times, of 128 bits by using a PCLMULQDQ instruction comprising performing a carry-less multiplication of two 64-bits operands;
folding of 64 bits by using the PCLMULQDQ instruction, providing a 64 bit message M′(x); and
calculating the 10-bit payload CRC value for the message M(x) by using a CRC-10 table-lookup algorithm;
wherein the folding of 128 bits and folding of 64 bits are adapted for use of the PCLMULQDQ instruction to calculate a 10-bit CRC by adapting degree of P(x)·K(x) to 32 by:
setting K(x)=X²², wherein P(x) is a polynomial of degree 10, and wherein·denotes the carry-less multiplication; and
performing the folding of 128 bits and folding of 64 bits by [M(x)·x²²]mod[P(x)·x²²].

33. The method of claim 32, wherein the message M(x) comprises a SYNC packet of type 1 or type 3 of Synchronization protocol, wherein the SYNC packet comprises the payload of a User Datagram Protocol (UDP) packet, the SYNC packet comprising a header of m bytes and a payload of n bytes, m=11 for SYNC packet of type 1 and m=19 for SYNC packet of type 3, the UDP packet comprising a UDP header and a UDP payload, the method further comprising performing, before the step of determining:
padding zero bytes of length k so as to adapt the sum of the SYNC packet payload length n and the k zero bytes to be a multiple of 16; and
allocating memory accessible by the processor so as to ensure a starting address of the SYNC packet payload to have a 16-bytes memory alignment.

34. The method of claim 33, wherein the padding comprises, for k less than or equal to m, padding zero bytes within the UDP payload.

35. The method of claim 34, wherein for k less than or equal to m, the allocating comprises allocating a memory buffer of length t in the memory, wherein the starting address of the UDP payload to hold the SYNC packet is determined by:
determining the size t of the aligned memory buffer to be (m+n)+16·[(m+n) mod16]; and
determining the starting address of the UDP payload to be starting address of the memory buffer+t−[(m+n)mod16].

36. The method of claim 35, wherein the starting address of the SYNC packet payload comprises the starting address of the UDP payload+m.

37. The method of claim 33, wherein the padding comprises, for k greater than m, padding zero bytes within the UDP header.

38. The method of claim 37, wherein for k greater than m, the allocating comprises allocating a memory buffer of length t in the memory, wherein the starting address of the UDP payload to hold the SYNC packet is determined by:
determining the size t of the aligned memory buffer to be k+n; and
determining the starting address of the UDP payload to be starting address of the memory buffer+(k−m).

39. The method of claim 38, wherein the starting address of the SYNC packet payload comprises the starting address of the memory buffer.

40. The method of claim 32, wherein the message M(x) comprises a SYNC packet according to Multimedia Broadcast and Multicast Services (MBMS) Synchronization protocol or according to enhanced Multimedia Broadcast and Multicast Services (eMBMS) Synchronization protocol.

41. The method of claim 32, wherein, in the determining the length of the message is determined to be less than 128, and wherein the adapting comprises padding zero bytes to make the message length 128 bits.

42. The method of claim 32, wherein, in the determining the length of the message is determined to be greater than 128 bits, and wherein the adapting comprises padding zero bytes to make the message length n*128 bits.

43. The method of claim 32, wherein P(x)=x¹⁰+x⁹+x⁵+x⁴+x+1, and P′(x)=P(x)·x₂₂=(x₃₂+x₃₁+x₂₇+x₂₆+x₂₃+x₂₂).

44. The method of claim 32, comprising, following the folding of 128 bits and folding of 64 bits and prior to calculating the 10-bit payload CRC value:
folding M″(x)·X²², providing a message M″(x) having a length larger than 64 bits;
adapting the length of M″(x) to 128 bits and folding of 64 bits by using the PCLMULQDQ instruction;
performing Barrett's reduction, providing 32-bits CRC; and
shifting the 32-bits CRC 22 bits to the right.

45. A device configured to calculate a 10-bit Cyclic Redundancy Check (CRC) value for a message M(x), the device comprising a processor and memory, the memory containing instructions executable by the processor whereby the device is operative to:
determine the length of the message to be greater than 64 bits;
adapt the message M(x) to have a length of n*128 bits, wherein n is a positive integral number;
fold, n-1 times, of 128 bits by using a PCLMULQDQ instruction comprising performing a carry-less multiplication of two 64-bits operands;
fold of 64 bits by using the PCLMULQDQ instruction, providing a 64 bit message M′(x); and
calculate the 10-bit payload CRC value for the message M(x) by using a CRC-10 table-lookup algorithm;
wherein the folding of 128 bits and folding of 64 bits are adapted for use of the PCLMULQDQ instruction to calculate a 10-bit CRC by:
adapting degree of P(x)·K(x) to 32 by setting K(x)=X²², wherein P(x) is a polynomial of degree 10, and wherein · denotes the carry-less multiplication; and
performing the folding of 128 bits and folding of 64 bits by [M(x)·x²²]mod[P(x)·x²²].

46. The device of claim 45, wherein the message M(x) comprises a SYNC packet of type 1 or type 3 of Synchronization protocol, wherein the SYNC packet comprises the payload of a User Datagram Protocol (UDP) packet, the SYNC packet comprising a header of m bytes and a payload of n bytes, m=11 for SYNC packet of type 1 and m=19 for SYNC packet of type 3, the UDP packet comprising a UDP header and a UDP payload, the device further being operative to, before the determining:
pad zero bytes of length k so as to adapt the sum of the SYNC packet payload length n and the k zero bytes to be a multiple of 16;
allocate memory accessible by the processor so as to ensure a starting address of the SYNC packet payload to have a 16-bytes memory alignment.

47. The device of claim 46, wherein the padding comprises, for k less than or equal to m, padding zero bytes within the UDP payload.

48. The device of claim 47, wherein for k less than or equal to m, the allocating comprises allocating a memory buffer of length t in the memory, wherein the device is operative to determine the starting address of the UDP payload to hold the SYNC packet by:
determining the size t of the aligned memory buffer to be (m+n)+16·[(m+n) mod16], and
determining the starting address of the UDP payload to be starting address of the memory buffer+t−[(m+n) mod16].

49. The device of claim 48, wherein the starting address of the SYNC packet payload comprises the starting address of the UDP payload+m.

50. The device of claim 45, wherein the padding comprises, for k greater than m, padding zero bytes within the UDP header.

51. The device of claim 50, wherein for k greater than m, the allocating comprises allocating a memory buffer of length t in the memory, wherein the device is operative to determine the starting address of the UDP payload to hold the SYNC packet by:
determining the size t of the aligned memory buffer to be k+n, and
determining the starting address of the UDP payload to be starting address of the memory buffer+(k−m).

52. The device of claim 51, wherein the starting address of the SYNC packet payload comprises the starting address of the memory buffer.

53. The device of claim 49, further being operative to:
fill the memory buffer with zero bytes;
read the payload of the SYNC packet to the starting address for the SYNC packet payload; and
determine the length of the message to be greater than 64 bits;
adapt the message M(x) to have a length of n*128 bits, wherein n is a positive integral number;
fold, n-1 times, of 128 bits by using a PCLMULQDQ instruction comprising performing a carry-less multiplication of two 64-bits operands;
fold of 64 bits by using the PCLMULQDQ instruction, providing a 64 bit message M′(x); and
calculate the 10-bit payload CRC value for the message M(x) by using a CRC-10 table-lookup algorithm;
wherein the folding of 128 bits and folding of 64 bits are adapted for use of the PCLMULQDQ instruction to calculate a 10 bit CRC by:
adapting degree of P(x)·K(x) to 32 by setting K(x)=X²², wherein P(x) is a polynomial of degree 10, and wherein·denotes the carry-less multiplication; and
performing the folding of 128 bits and folding of 64 bits by [M(x)·x ²²]mod[P(x)·x²²].

54. The device of claim 45, wherein the message M(x) comprises a SYNC packet according to Multimedia Broadcast and Multicast Services (MBMS) Synchronization protocol or according to enhanced Multimedia Broadcast and Multicast Services (eMBMS) Synchronization protocol.

55. The device of claim 45, wherein the device is operative to determine the length of the message to be less than 128, and wherein the device is operative to adapt by padding zero bytes to make the message length 128 bits.

56. The device of claim 45, wherein, the device is operative to determine the length of the message to be greater than 128 bits, and wherein the device is operative to adapt by padding zero bytes to make the message length n*128 bits.

57. The device of claim 45, wherein P(x)=x¹⁰+x⁹+x⁵+x⁴+x+1, and P′(x)=P(x)·x²²=(x³²+x³¹+x²⁷+x²⁶+x²³+x²²).

58. The device of claim 45 wherein the device is operative to, following the folding of 128 bits and folding of 64 bits and prior to calculating the 10-bit payload CRC value:
fold M″(x)=M′(x)·X²², providing a message M″(x) having a length larger than 64 bits,
adapt the length of M″(x) to 128 bits and folding of 64 bits by using the PCLMULQDQ instruction,
perform Barrett's reduction, providing 32 bits CRC, and
shift the 32 bits CRC 22 bits to the right.

59. A non-transitory computer-readable medium comprising, stored thereupon, a computer program for a device configured to calculate a 10-bit Cyclic Redundancy Check (CRC) value for a message M(x), the computer program comprising computer program code configured so that when the computer program code is run on the device the computer program code causes the device to:
determine the length of the message to be greater than 64 bits;
adapt the message M(x) to have a length of n*128 bits, wherein n is a positive integral number;
fold, n-1 times, of 128 bits by using a PCLMULQDQ instruction comprising performing a carry-less multiplication of two 64-bits operands;
fold of 64 bits by using the PCLMULQDQ instruction, providing a 64-bit message M′(x); and
calculate the 10-bit payload CRC value for the message M(x) by using a CRC-10 table-lookup algorithm;
wherein the folding of 128 bits and folding of 64 bits are adapted for use of the PCLMULQDQ instruction to calculate a 10 bit CRC by:
adapting degree of P(x)·K(x) to 32 by setting K(x)=X²², wherein P(x) is a polynomial of degree 10, and wherein · denotes the carry-less multiplication; and
performing the folding of 128 bits and folding of 64 bits by [M(x)·x²²]mod[P(x)·x²²].
